(19) United States
(12) Patent Application Publication
(10) Pub. No.: US 2023/0013187 A1
(43) Pub. Date: Jan. 19, 2023

(54) SPLIT-SEL CMOS IMAGE SENSOR PIXEL

(71) Applicant: SHENZHEN GOODIX TECHNOLOGY CO., LTD., Shenzhen (CN)

(72) Inventors: Yunfei GAO, San Diego, CA (US); Yu Hin Desmond CHEUNG, San Diego, CA (US); Tae Seok OH, San Diego, CA (US); Jinwen XIAO, San Diego, CA (US)

(21) Appl. No.: 17/374,997

(22) Filed: Jul. 14, 2021

(51) Int. Cl. H01L 27/146

(52) U.S. Cl. CPC H01L 27/14603; H01L 27/14614; H01L 27/14616

(57) ABSTRACT

Techniques are described for implementing a split-select-block (split-SEL) complementary metal-oxide semiconductor (CMOS) image sensor (CIS) pixel physical architecture, such as for reducing noise in low-light application contexts. The split-SEL CIS pixel physical architecture can include a pixel block with one or more photodiodes. Above the photodiodes, there can be: a first oxide diffusion region with a reset block and a gain block disposed thereon; and a second oxide diffusion region with a select block disposed thereon. Below the photodiodes, there can be a third oxide diffusion region with a source follower (SF) block (e.g., a square-gate SF transistor) disposed thereon. A trace can be routed through the set of photodiodes to couple the source of the SF block with the select block. The architecture permits an appreciable increase in the physical gate length and/or other features.

### FIELD

The present invention relates generally to complementary metal-oxide semiconductor (CMOS) image sensors. More particularly, embodiments relate to split-SEL (select block) pixel designs for use with CMOS image sensors (CISs).

### BACKGROUND

Many modern electronics applications include integrated digital cameras and/or other imaging systems, which are based on complementary metal-oxide semiconductor (CMOS) image sensor (CIS) technologies. A CIS can typically include an array of pixels, each including a single photo-sensor (e.g., photodiode), or a grouping of multiple photo-sensors. Each pixel can also include supporting hardware, such as a select gate for selecting the pixel and a source-follower transistor for converting the optical responses of the photo-sensors into corresponding electrical signals for use by other components. Performance of a pixel can relate to its size. For example, increasing the size of the photodiode area in the pixel can increase the photodiode's full-well capacitance (FWC), which tends to support higher dynamic range, higher contrast, and/or other image performance improvements. Similarly, increasing the active area of the source-follower transistor can improve the pixel's noise performance, such as by increasing its signal-to-noise ratio (SNR).

For any given pixel size, the footprint must be shared by both the photo-sensor(s) and the supporting hardware. As such, any increase in the size of one forces a decrease in the size of the other, such that the pixel design conventionally represents a trade-off between image performance (relating largely to size and corresponding FWC of the photo-sensors) and noise performance (relating largely to active area of the source-follower transistor). As pixel dimensions continue to decrease, it becomes increasingly difficult to maintain acceptable noise performance while optimizing FWC.

### BRIEF SUMMARY OF THE INVENTION

Embodiments provide circuits, devices, and methods for implementing a split-select-block (split-SEL) complementary metal-oxide semiconductor (CMOS) image sensor (CIS) pixel physical architecture, such as for reducing noise in low-light application contexts. The split-SEL CIS pixel physical architecture can include a pixel block with one or more photodiodes. Above the photodiodes, there can be: a first oxide diffusion region with a reset block and a gain block disposed thereon; and a second oxide diffusion region with a select block disposed thereon. Below the photodiodes, there can be a third oxide diffusion region with a source follower (SF) block (e.g., a square-gate SF transistor) disposed thereon. A trace can be routed through the set of photodiodes to couple the source of the SF block with the select block. The architecture permits an appreciable increase in the physical gate length and/or other features.

According to one set of embodiments, a split-select-block (split-SEL) complementary metal-oxide semiconductor (CMOS) image sensor (CIS) pixel physical architecture is provided. The architecture includes: a pixel block having a set of photodiodes; a first oxide diffusion region above the set of photodiodes and having, disposed thereon, a reset block to reset the pixel block and a gain block to provide dynamic control gain (DCG) to the pixel block; a second oxide diffusion region above the set of photodiodes and having, disposed thereon, a select block to select the pixel block, the select block having a control contact and a read-out contact; a third oxide diffusion region below the set of photodiodes and having, disposed thereon, a source follower block having a source contact, a drain contact, and a gate contact; and a trace routed through the set of photodiodes to couple the source contact with the control contact. In some such embodiments, the source follower block comprises a square-gate source follower (SGSF) transistor.

According to another set of embodiments, a split-SEL source-follower transistor system is provided. The system includes: a source follower transistor disposed on an oxide diffusion region of a pixel architecture, the oxide diffusion region electrically isolated from a select block of the pixel architecture, the source follower transistor comprising: an active layer comprising a source-doped region separated from a first drain-doped region by a first current channel, and separated from a second drain-doped region by a second current channel; and a square-gate layer comprising: a first main-gate region disposed above the first current channel to a first side of the source-doped region; and a second main-gate region, coupled with the first main-gate region, and disposed above the second current channel to a second side of the source-doped region opposite the first side of the source-doped region. In some such embodiments, the oxide diffusion region is a first oxide diffusion region, and the system further includes: a second oxide diffusion region, electrically isolated from the first oxide diffusion region, and having the select block disposed thereon, the select block including a control contact and a read-out contact; and a trace to couple the source-doped region with the control contact.

### BRIEF DESCRIPTION OF THE DRAWINGS

The accompanying drawings, referred to herein and constituting a part hereof, illustrate embodiments of the disclosure. The drawings together with the description serve to explain the principles of the invention.

FIG. 1 shows a simplified block diagram of a portion of an illustrative digital imaging system, as context for various embodiments described herein.

FIG. 2 shows a top view of a conventional square-gate source-follower (SGSF) transistor.

FIG. 3 shows a simplified pixel schematic for an illustrative conventional CIS pixel having a source follower transistor, according to various embodiments.

FIG. 4 shows a simplified conventional physical layout of an illustrative CIS pixel having an integrated SGSF transistor.

FIG. 5 shows simplified physical split-SEL layouts for illustrative CIS pixels, according to various embodiments described herein.

FIG. 6 shows an example of a reconfigured SGSF transistor, according to various embodiments described herein.

In the appended figures, similar components and/or features can have the same reference label. Further, various components of the same type can be distinguished by following the reference label by a second label that distinguishes among the similar components. If only the first reference label is used in the specification, the description is applicable to any one of the similar components having the same first reference label irrespective of the second reference label.

### DETAILED DESCRIPTION OF THE INVENTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

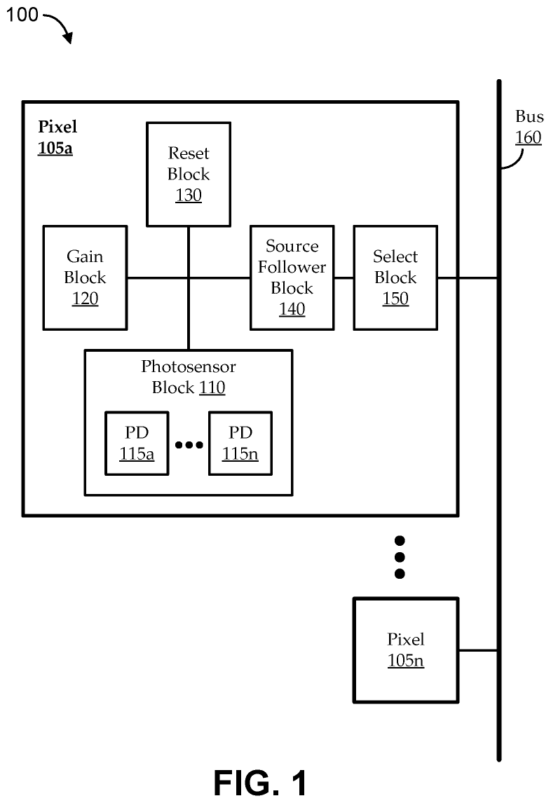

FIG. 1 shows a simplified block diagram of a portion of an illustrative digital imaging system 100, as context for various embodiments described herein. The digital imaging system 100 is built around a complementary metal-oxide semiconductor (CMOS) image sensor (CIS) technology. Such a CIS system can typically include an array of pixels 105, such as millions of pixels 105 arranged in rows and columns. Each pixel 105 can include a photo-sensor block 110, which can include a single photodiode 115 (e.g., or any suitable photo sensor), or a grouping of multiple photodiodes 115. For example, each pixel 105 can be implemented with a grouping of four photodiodes 115 arranged in a color filter array (CFA) arrangement, such as a Bayer color pattern (e.g., one red photodiode 115, one blue photodiode 115, an two green photodiodes 115), or any other suitable pattern.

The pixel 105 also includes additional components to facilitate sage of the photo-sensor block 110 for optical sensing. As illustrated, embodiments can include a gain block 120, a reset block 130, a source-follower block 140, and a select block 150. The gain block 120 can control gain for the pixel 105, such as by implementing dual conversion gain (DCG). The reset block 130 can selectively reset the pixel 105 components. The source-follower block 140 can support conversion of outputs from the photo-sensor block 110 into an electrical signal indicative of optical information detected by the photo-sensor block 110. The select block 150 can support selection of the pixel 105 signals from among the array of pixels 105, for example responsive to a control signal received via a bus 160. For example, the bus 160 may be a column select bus, or the like.

As technology progresses, new applications continue to push for reductions in the sizes of image sensor pixels 105. Indeed, many digital imaging applications are seeking ever-increasing numbers and densities of pixels 105 on their image sensor chips (i.e., driving decreases in pixel 105 sizes), while also demanding that designs continue to meet or exceed multiple performance parameters, such as relating to image contrast, dynamic range, capture frame-rate, signal-to-noise ratio (SNR), power consumption, etc. However, it has been demonstrated that certain performance parameters of pixels 105 tend to be adversely impacted by reducing the sizes of components within the pixel 105. For example, decreasing the size of a photodiode 115 in the photo-sensor block 110 can decrease its full-well capacitance (FWC), which can tend to yield lower dynamic range, lower contrast, and/or other image performance reductions. Similarly, decreasing the active area of the source-follower block 140 can reduce the pixel's 105 noise performance, such as by reducing its signal-to-noise ratio (SNR). For example, decreasing the active area of the source-follower block 140 can tend to increase its susceptibility to low-frequency noise (sometimes referred to as 1/f noise), and/or burst noise (also referred to as random telegraph signal (RTS) noise, impulse noise, bi-stable noise, etc.). Some conventional pixel 105 designs seek to maximize component sizes within the limited footprint of the pixel 105, but the footprint of each pixel 105 is shared by all its components; increasing the size of one component (e.g., the photo-sensor block 110) tends to require decreasing the size of another (e.g., source-follower block 140). As such, conventional pixel 105 designs are often forced into a trade-off between image performance (relating to size and corresponding FWC of the photo-sensors) and noise performance (relating to active area of the source-follower transistor).

As pixel 105 dimensions continue to decrease, it is becoming increasingly difficult even to reach an acceptable trade-off between image performance and noise performance. One advanced approach to addressing this trade-off is integration of so-called “square-gate” source followers, or the like. Examples of square-gate source followers are described and illustrated in U.S. patent application Ser. No. 17/141,141, titled “SQUARE-GATE SOURCE-FOLLOWER FOR CMOS IMAGE SENSOR PIXEL,” filed on Jan. 4, 2021, which is hereby incorporated by reference in its entirety. Square-gate source followers are configured in a manner that effectively increases (e.g., doubles) the gate width, thereby increasing the transconductance of the source-follower and reducing the RTS noise.

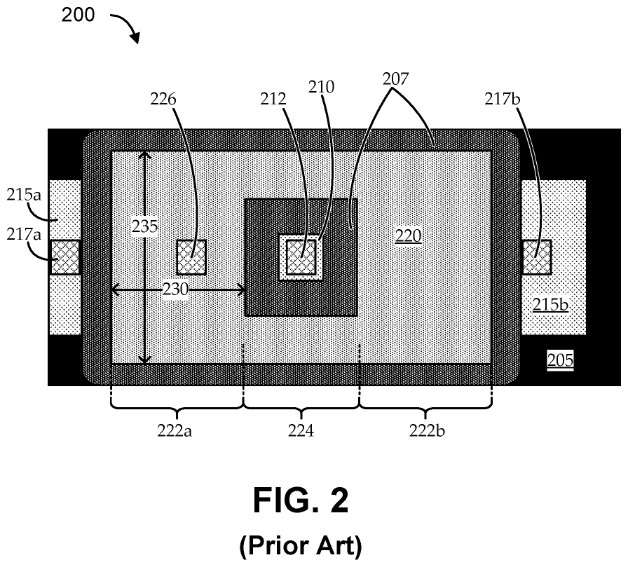

For the sake of added context, FIG. 2 shows a top view of a conventional square-gate source-follower (SGSF) transistor 200. As illustrated, embodiments of the SGSF transistor 200 include an active layer 205 and a square-gate layer 220. Embodiments can also include various insulation layers and related structures. Some implementations include inter-layer structures 207, such as silicon nitride spacers, insulating oxide layers, etc. Some implementations include shallow-trench isolation (STI) regions and/or other edge isolation structures (not shown), such as to isolate between transistors and/or other components on the substrate of the pixel.

The active layer 205 can be implemented using a silicon substrate, such as a portion of a silicon wafer. The active layer 205 includes a drain-doped region 210 separated from a first source-doped region 215a by a first current channel, and separated from a second source-doped region 215b by a second current channel. Each of the drain-doped region 210 and the source-doped regions 215 are denoted by dashed circles intended to represent the approximate locations of the respective regions. In some implementations, each of the drain-doped region 210 and the source-doped regions 215 are n-doped regions (e.g., wells) in a p-doped substrate, such that application of a voltage proximate to the current channels causes current to flow in parallel from the drain-doped region 210 to the two source-doped regions 215. Alternatively, each of the drain-doped region 210 and the source-doped regions 215 can be p-doped regions (e.g., wells) in an n-doped substrate, such that application of a voltage proximate to the current channels restricts current from flowing in the current channels between the drain-doped region 210 to the source-doped regions 215.

As used herein in context of current, the term “parallel” is intended to mean electrically (not necessarily geometrically) parallel. In particular, references to “parallel” current channels means that current from a single circuit node (e.g., the drain-doped region 210) splits along multiple current paths (e.g., to two separate source-doped regions 215) along independent paths, regardless of the geometric relationship between those paths. For example, the current channels in the illustrated SGSF transistor 200 provide parallel current paths between the drain and source regions of the transistor, even though they are geometrically collinear (not geometrically parallel to each other). Further, the term “current channels” is used herein to refer to a region through which current is intended to flow by design under particular operating conditions, even if current is not presently flowing in that region. For example, one of ordinary skill in the art will understand that references herein to the drain-doped region 210 being separated from source-doped regions 215 by current channels provides a clear description of the physical relationship between the drain-doped region 210 and the source-doped regions 215, even when the device is not operating and/or no current is otherwise flowing.

Embodiments of the square-gate layer 220 include at least two main-gate regions 222 that are coupled together to form the “square-gate”. The embodiments shown in FIG. 2 has two side-gate regions 224 that couple together the main-gate regions 222, geometrically forming a square around the drain-doped region 210. Some other embodiments have two main-gate regions 222 coupled by a single side-gate region 224, such as geometrically forming a C-shape around three-fourths of the drain-doped region 210. Some other embodiments have no side-gate regions 224 and couple the main-gate regions 222 together in other ways. For example, the “square-gate” looks like two fingers on opposite sides of the drain-doped region 210, and those fingers are coupled using conductive paths, vias, or in any other suitable manner.

Regardless of the manner of coupling together the main-gate regions 222, embodiments can use a single gate contact 226 to control voltage to the entire square-gate layer 220 (i.e., at least to both main-gate regions 222). The drain-doped region 210 has a drain contact 212 electrically coupled with and disposed thereon. Each of the source-doped regions 215 has a respective source contact 217 electrically coupled with and disposed thereon. Each main-gate region 222 of the square-gate layer 220 is disposed above a respective current channel to a respective side of the drain-doped region 210 opposite each other. For example, the first main-gate region 222a is disposed above a first current channel between the drain-doped region 210 and the first source-doped region 215a, and the second main-gate region 222b is disposed above a second current channel between the drain-doped region 210 and the second source-doped region 215b. The two current channels effectively cause the drain current to split along the two current channels 225 and flow in opposite directions to the sources. In some implementations, the current channels are designed to be matched, such as by being equivalent in channel length, doping, etc., such that current will split substantially equally between the channels.

Each current channel has a channel length (L) 230 over which the current travels between the drain-doped region 210 and a respective source-doped region 215. Similarly, at least because of doping parameters and edge isolation structures, the active region of the active layer 205 has a definable width (W) 235. The channel length 230 and active region width 235 are closely related to the length and width, respectively of the main-gate region 222 disposed above each channel. As such, the description generally uses length 230 (or L 230) to refer both to the channel length of each current channel and to the physical length of each main-gate region 222, and the description generally uses width 235 (or W 235) to refer both to the active region width and to the physical width of each main-gate region 222. The length 230 and width 235 are controlled, at least in part, by pixel design parameters and manufacturing process constraints. For example, as noted above, the pixel footprint design balances allocated space between the photo-sensor block 110 and supporting components, including the source follower block 140 (which can be implemented by the SGSF transistor 200). The allocated space can typically define the maximum (or nominal) length and width of transistor components.

By having parallel matched current channels, the SGSF transistor 200 architecture doubles the active region width 235 without changing the physical width of the main-gate regions 222 (or of the overall source-follower transistor). As such, the SGSF transistor 200 manifests operationally as a source-follower transistor that is the same length L 230 and twice the width 235. It can be demonstrated that transconductance of source-follower transistors is proportional to W 235 and inversely proportional to L 230; or proportional to a ratio of W to L (i.e., to W divided by L). As such, doubling W with the same L can nominally double the transconductance of the transistor. For example, a transconductance relationship for a source-follower transistor can be described as follows:

$${ℊ}_{m}^{2} = 2 {C}_{ox} {μ}_{eff} \frac{W}{Lm} {I}_{D} = ( 2 {μ}_{eff} \frac{{ε}_{0} {ε}_{OX}}{m} {I}_{D} ) ( \frac{W}{{L}_{ℊ} {ℊ}_{OX}} ) ,$$

where g_m is the transconductance, and I_D is the drain current (i.e., essentially the output of the transistor). Other parameters, such as C_ox (oxide capacitance), μ_eff (effective gain), m (body coefficient), and g_ox (oxide thickness) tend to be relatively constant and dependent on the manufacturing process and other such characteristics.

Increasing W 235 relative to L 230 (e.g., nominally doubling W 235) can provide a number of features. One such feature is that higher transconductance can support operation at higher frame rates of image acquisition. Another such feature arises from the transconductance being linearly proportional to the product of the drain current and the W/L ratio (as shown in the relationship above). As such, by increasing the W/L ratio, the same transconductance can be achieved with lower current, and thereby with lower power consumption. Other such features relate to noise performance. One noise performance-related feature is based on channel implant depth typically representing a trade-off between transconductance-related performance (e.g., efficiency) and noise-related performance. Increasing the W/L ratio can allow the same transconductance to be achieved with smaller surface carrier density (e.g., with deeper channel implanting), and thereby with less associated noise. Another noise performance-related feature relates to the shape of the square-gate, which can produce regions of overlap between the square-gate layer 220 and edge isolation structures 240 that are longer current paths than the primary current paths through the main-gate regions 222 and therefore tend to suppress current flow along the length-wise edges of the SGSF transistor 200. Because the length-wise edges can tend to have high electric field strengths that trap electrons and produce relatively high amounts of noise, suppressing current flow through those regions can reduce noise.

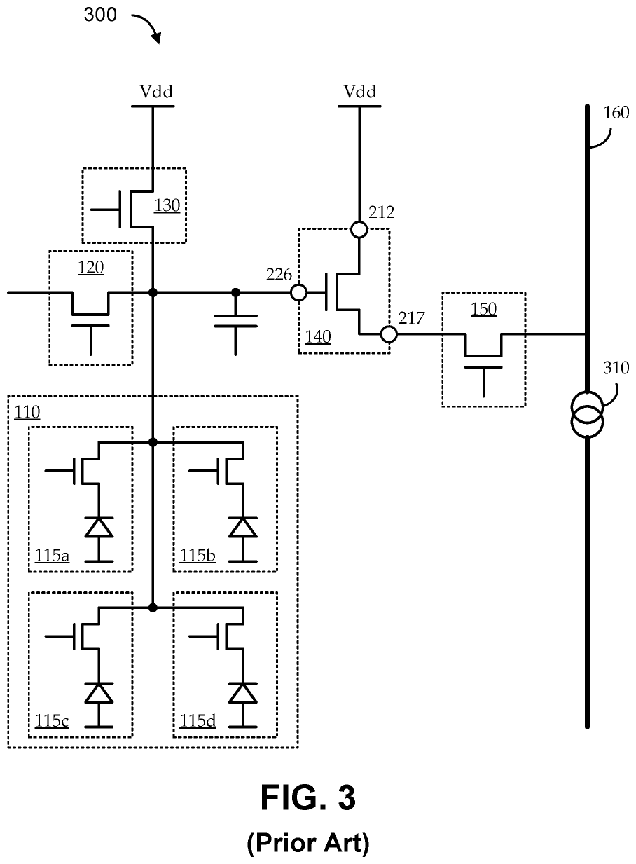

FIG. 3 shows a simplified pixel schematic 300 for an illustrative conventional CIS pixel having a source follower transistor 140, according to various embodiments. The schematic can represent the CIS pixel 100 shown in FIG. 1. The source follower transistor 140 can be implemented as the source follower transistor 200 of FIG. 2, or as any conventional (e.g., planar gate) source follower. As illustrated, the schematic includes a photo-sensor block 110 with four photodiodes 115, a gain block 120, a reset block 130, a select block 150, and the source follower transistor 140 (an implementation of source follower block 140). For added clarity, the schematic of the source follower transistor 140 is shown with schematic representations of the drain contact 212, the source contact 217, and the gate contact 226. In an SGSF transistor 200 implementation, the source follower transistor 140 could be represented as two field-effect transistors (FETs) with a shared drain node, gates coupled together, and a single source node (e.g., a single source contact 217, coupled together contacts of separate source-doped regions, etc.). In the illustrated configuration, the drain contact 212 is coupled with a voltage reference (Vdd). Applying a gate voltage at gate contact 226 actuates the source follower transistor 140 (e.g., causing current to flow in parallel from the common drain node to the respective source nodes of both FETs in an SGSF transistor 200 implementation).

The schematic 300 clearly shows that the select block 150 is coupled between the source contact 217 and a bus 160. For example, the bus 160 is a column select bus with a bias current source 310. At least because of the direct coupling between the source contact 217 and the select block 150, conventional physical integrated circuit layouts place the select block 150 directly adjacent to the source follower transistor 140, typically disposed on a shared oxide diffusion region 310 and sharing a contact.

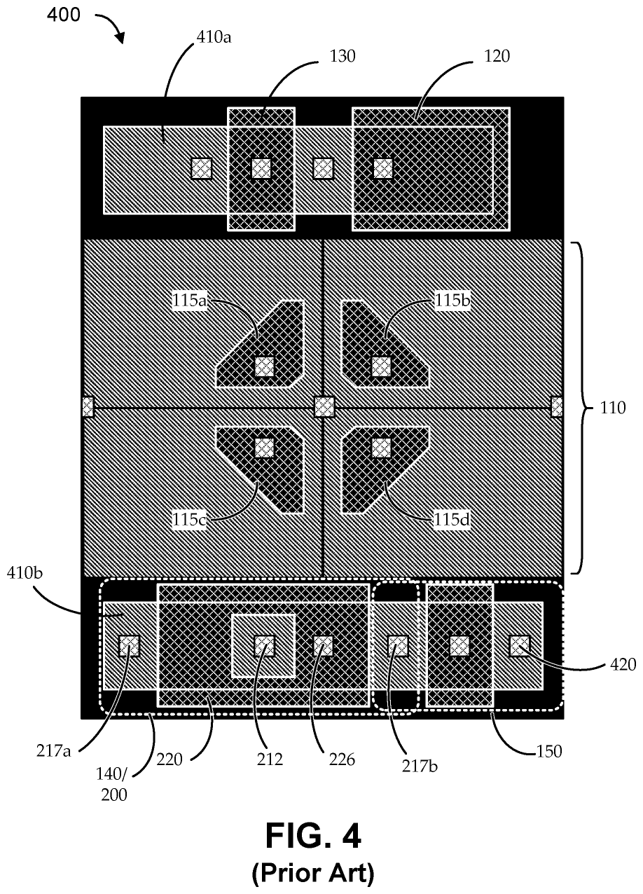

FIG. 4 shows a simplified conventional physical layout 400 of an illustrative CIS pixel having an integrated SGSF transistor 200. The physical layout 400 can be a physical layout implementation of the simplified pixel schematic 300 of FIG. 3. A center region of the illustrated layout 400 includes a photo-sensor block 110 with four photodiodes 115. An upper portion of the illustrated layout 400 includes a gain block 120 and a reset block 130, with corresponding contacts. A lower portion of the illustrated layout 400 includes a select block 150 and the conventional SGSF transistor 200 of FIG. 2. As noted with reference to FIG. 3, the layout 400 shows the select block 150 and the conventional SGSF transistor 200 being disposed on a same lower oxide diffusion region 410b and sharing a contact 217b (one of the source contacts of the source follower transistor 140 is also one of the contacts of the select block 150). The gain block 120 and reset block 130 are also illustrated as being disposed on a same upper oxide diffusion region 410a.

In some implementations, such a physical layout 400 can be for a standard 2-by-2 CIS pixel layout. In other implementations, the physical layout 400 can represent a portion of a standard 4-by-2 CIS pixel layout (e.g., another photo-sensor block 110 with four additional photodiodes 115 can be implemented below the lower portion of the layout 400, and all eight photodiodes 115 can share the gain block 120, reset block 130, select block 150, and SGSF transistor 200). Lengths, widths, and placement of component blocks are controlled at least by various design and manufacturing constraints. One such constraint defines a maximum total size of the physical layout, such that increasing the size of one component can force a reduction in the size of another component. For example, as described above, it can be desirable (e.g., for improving transconductance, noise performance, and/or other parameters) to increase the effective width of the source follower. Increasing the physical width of the source follower, as with a larger conventional planar-gate source follower, would force a trade-off with the size of the photodiodes 115, which can be undesirable. However, the SGSF transistor 200 increases (e.g., doubles) the effective width of the source follower without increasing the physical width by consuming more length to provide parallel matched current channels.

Still, the physical dimensions of the SGSF transistor 200 are constrained for various reasons. Conventional design constraints tend to limit the physical width of the source follower block 140 (e.g., the SGSF transistor 200) based on a desire to maximize the size of the photodiodes 115 (i.e., not to reduce their size in favor of a larger source follower). Conventional design constraints tend to limit the physical length of the source follower block 140 based on constraints relating to the oxide diffusion region 410b and/or contacts. For example, the placement of the select block 150 allows one of its contacts to be shared directly with the source contact 217b of the source follower block 140, and leaves the other of its contacts available for use as a read-out contact 420. To isolate the read-out contact 420 from adjacent components (e.g., the right-adjacent oxide diffusion region of the adjacent pixel, not shown), the oxide diffusion region 410b ends immediately to the right of the read-out contact 420, and a minimum length of space is left (i.e., without oxide diffusion, contacts, etc.). As such, it can be seen that the physical length of the source follower block 140 is effectively limited by the placement of the select block 150. In typical conventional designs, such a restriction of length is not considered to be a constraint, at least because, as described above, transconductance of the source follower block 140 tends to be inversely proportional to its length. Because conventional designs generally seek to maximize transconductance (e.g., to maximize conversion gain, frame rate, etc.), there is typically no design motivation to increase the length of the source follower block 140.

Still, as noted above, a primary source of noise experienced by the photodiodes 115 is RTS noise from the source follower, and the amount of the RTS noise relates to the total footprint (i.e., the length and width of the gate area) of the source follower. Increasing the total gate area can decrease the amount of noise. Integration of a conventional SGSF transistor 200 can allow the effective width to increase (e.g., double), thereby appreciably reducing noise relative to a similar-physical-width planar-type source follower. However, for some low-light applications, even very small amounts of noise can interfere with operation; even with a conventional SGSF transistor 200, the level of RTS noise can impact low-light performance levels.

Embodiments described herein provide techniques to increase the length of the source follower (e.g., the gate length of the SGSF transistor 200) to reduce noise for low-light applications. Such techniques split the select block 150 away from the source follower block 140, such that they do not share oxide diffusion region 410b, and can also reconfigure the SGSF transistor. Using such techniques, the gate length of the SGSF transistor can be appreciably increased, which can further reduce RTS noise. Notably, such an increase in gate length will also tend to decrease transconductance of the SGSF transistor. Such an impact to transconductance may be acceptable in low-light applications, which may be able to tolerate lower conversion gain, lower frame rate, etc.

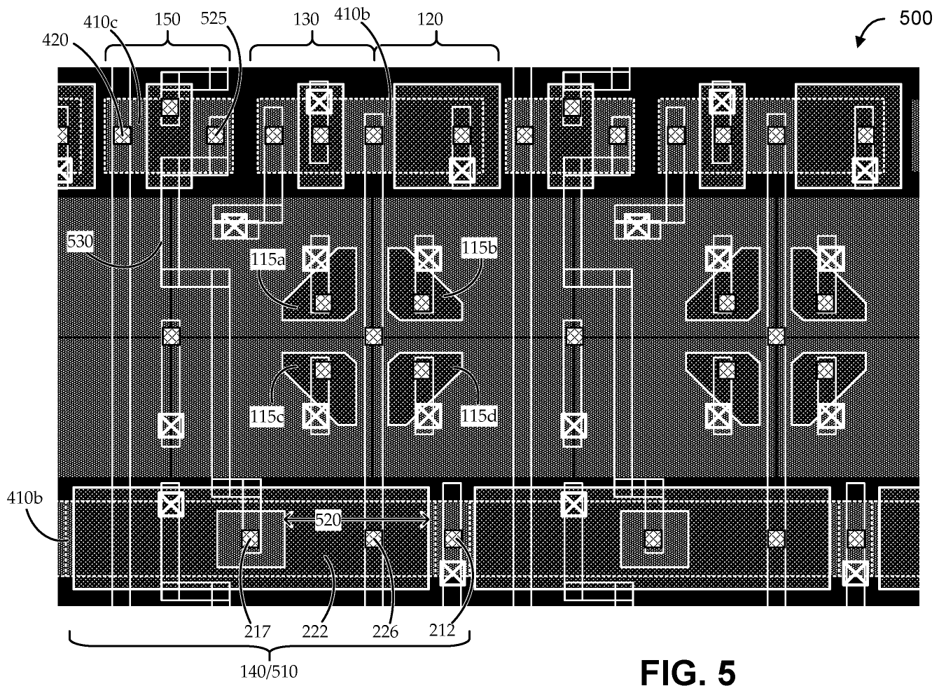

FIG. 5 shows simplified physical split-SEL layouts 500 for illustrative CIS pixels, according to various embodiments described herein. The physical split-SEL layouts 500 can be novel physical layout implementations of the simplified pixel schematic 300 of FIG. 3. For added clarity, the physical split-SEL layouts 500 show two adjacent instances of the novel split-SEL architecture. To avoid over-complicating the description, the term “layout” is used to refer to each instance, such that each physical split-SEL layout 500 includes a pixel block 110, a gain block 120, a reset block 130, and a source follower block 140; and FIG. 5 shows two such physical split-SEL layouts 500. Such physical split-SEL layouts 500 can be used to implement 2-by-2 CIS pixel layouts, 4-by-2 CIS pixel layouts (e.g., with a lower block of four photo-sensors not shown), or other suitable layouts.

As in the conventional layout 400 of FIG. 4, a center region of the illustrated physical split-SEL layout 500 includes a photo-sensor block 110 with four photodiodes 115; and an upper portion of the illustrated physical split-SEL layout 500 includes a gain block 120 and a reset block 130 with corresponding contacts, sharing an upper oxide diffusion region 410a. Unlike the conventional layout 400 of FIG. 4, the lower portion of the physical split-SEL layout 500 includes only a reconfigured SGSF transistor 510 on its own lower oxide diffusion region 410b, and the select block 150 is moved to the upper portion of the physical split-SEL layout 500 on a separate upper oxide diffusion region 410c.

The reconfigured SGSF transistor 510 includes various features. One feature is that moving the select block 150 out of the lower oxide diffusion region 410b allows the gate length (illustrated by arrow 520) of the reconfigured SGSF transistor 510 can be appreciably longer. For example, using an example state-of-the-art manufacturing process to implement CIS pixels according to the illustrative physical layout 400 of FIG. 4, the maximum gate length of the conventional SGSF transistor 200 may be around 0.35 microns; while, using the same example state-of-the-art manufacturing process to implement CIS pixels according to the physical split-SEL layouts 500 of FIG. 4, the maximum gate length of the reconfigured SGSF transistor 510 may be up to around 0.80 microns (i.e., more than twice the length). As noted above, the increase in gate length can reduce RTS noise from the source follower block 140.

Another feature is that the reconfigured SGSF transistor 510 has a single source-doped region 215 with a single source contact 217 located in toward the center of the source follower block 140, and a single drain-doped region 210 with a single drain contact 212 at the outside of the source follower block 140. This is essentially the opposite of the conventional SGSF transistor 200 configuration illustrated in FIGS. 2 and 4. As described above, the select block 150 includes two contacts on either of its sides: a first contact (a control contact 525) to couple with the source follower, and a second contact to couple with a read-out bus (read-out contact 420). As illustrated, the physical split-SEL layout 500 includes a dedicated trace 530 to couple the reconfigured source contact 217 (still in the lower portion of the layout 500) with the control contact 525 of the relocated select block 150 (now in the upper portion of the layout 500). The trace 530 crosses the pixel block 110. With the select block 150 on its own upper oxide diffusion region 410c, the read-out contact 420 of the relocated select block 150 is left accessible for coupling with the bus, while also being isolated from neighboring components.

Another feature is that reconfiguration of the source-doped region 215 and the drain-doped region 210 permits placement of multiple reconfigured SGSF transistors 510 directly adjacent to each other. As described above (e.g., in the circuit schematic 300 of FIG. 3), the drain contact 212 is coupled with Vdd. As such, with the drain contact 212 to the outside of the source follower block 140, another reconfigured SGSF transistor 510 can be placed directly adjacent thereto. In some embodiments, multiple adjacent reconfigured SGSF transistors 510 share the same lower oxide diffusion region 410b. For example, there is no need to isolate the drain contact 212 from neighboring components by ending the oxide diffusion region and leaving space, as in the conventional layout 400 where the read-out contact 420 is in the corresponding location. This can provide various features, such as allowing the gate length of the reconfigured SGSF transistor 510 to be even longer.

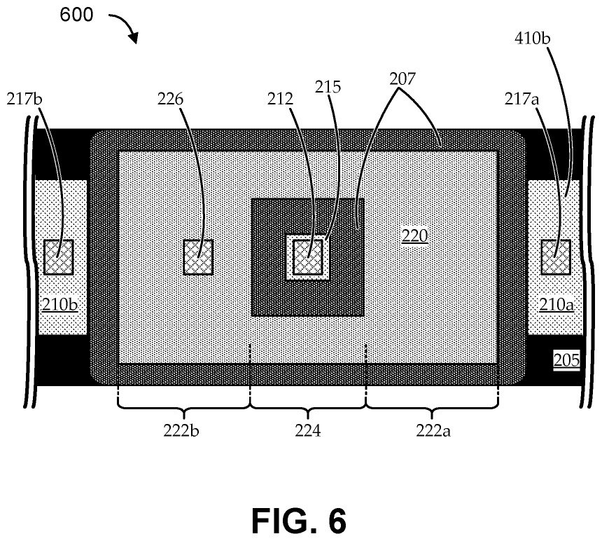

For the sake of illustration, FIG. 6 shows an example of a reconfigured SGSF transistor 600, according to various embodiments described herein. The reconfigured SGSF transistor 600 is an implementation of the reconfigured SGSF transistor 510. As illustrated, the reconfigured SGSF transistor 600 includes an active layer with a source-doped region 215 separated from a first drain-doped region 210a by a first current channel, and separated from a second drain-doped region 210b by a second current channel. The first and second current channels can be matched (e.g., having the same nominal length, as described above). A first main-gate region 222a is disposed above the first current channel to a first side of the source-doped region 215, and a second main-gate region 222b is coupled with the first main-gate 222a region and is disposed above the second current channel to a second side of the source-doped region 215 opposite the first side of the source-doped region 215.

When multiple, adjacent reconfigured SGSF transistors 600 are implemented on a shared lower oxide diffusion region 410b, at least a portion of the reconfigured SGSF transistors 600 can share drain-doped regions 210 (and/or share drain contacts 212). For example, the first drain-doped region 210a shown as part of the reconfigured SGSF transistor 600 may also be a respective second drain-doped region 210b of another reconfigured SGSF transistor 600 (not shown) that is directly adjacent to the right of the illustrated reconfigured SGSF transistor 600 and sharing the same lower oxide diffusion region 410b; and/or the second drain-doped region 210b shown as part of the reconfigured SGSF transistor 600 may also be a respective first drain-doped region 210a of another reconfigured SGSF transistor 600 (not shown) that is directly adjacent to the left of the illustrated reconfigured SGSF transistor 600 and sharing the same lower oxide diffusion region 410b.

Returning to FIG. 5, another feature is that, because the added length provides an appreciable increase in transconductance, some applications can tolerate a reduction in the physical width of the reconfigured SGSF transistor 510. As described above, the transconductance is proportional to the total gate area (length times width), such that reducing the width will reduce the transconductance. However, with the increased effective width resulting from use of the square-gate design, and the increased physical length due to the novel split-SEL architecture and reconfigured SGSF transistor 510 design, a sufficient amount of transconductance can still be provided for some applications even with a reduced physical gate width. Reducing the physical gate width can open up additional area for increasing the footprint of the pixel block 110 (of the photodiodes 115). As noted above, the larger photodiodes 115 can have larger full well capacitance for improved performance.

It will be understood that, when an element or component is referred to herein as “connected to” or “coupled to” another element or component, it can be connected or coupled to the other element or component, or intervening elements or components may also be present. In contrast, when an element or component is referred to as being “directly connected to,” or “directly coupled to” another element or component, there are no intervening elements or components present between them. It will be understood that, although the terms “first,” “second,” “third,” etc. may be used herein to describe various elements, components, these elements, components, regions, should not be limited by these terms. These terms are only used to distinguish one element, component, from another element, component. Thus, a first element, component, discussed below could be termed a second element, component, without departing from the teachings of the present invention, As used herein, the terms “logic low,” “low state,” “low level,” “logic low level,” “low,” or “0” are used interchangeably. The terms “logic high,” “high state,” “high level,” “logic high level,” “high,” or “1” are used interchangeably.

As used herein, the terms “a”, “an” and “the” may include singular and plural references. It will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components. Furthermore, as used herein, the words “and/or” may refer to and encompass any possible combinations of one or more of the associated listed items.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments, as well as other embodiments, will be apparent to those of skill in the art upon reference to the description. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof. Those of skill in the art will appreciate variations of the above-described embodiments that fall within the scope of the invention. As a result, the invention is not limited to the specific embodiments and illustrations discussed above, but by the following claims and their equivalents.

What is claimed is:

1. A split-select-block (split-SEL) complementary metal-oxide semiconductor (CMOS) image sensor (CIS) pixel physical architecture comprising:
a pixel block having a set of photodiodes;
a first oxide diffusion region above the set of photodiodes and having, disposed thereon, a reset block to reset the pixel block and a gain block to provide dynamic control gain (DCG) to the pixel block;
a second oxide diffusion region above the set of photodiodes and having, disposed thereon, a select block to select the pixel block, the select block having a control contact and a read-out contact;
a third oxide diffusion region below the set of photodiodes and having, disposed thereon, a source follower block having a source contact, a drain contact, and a gate contact; and
a trace routed through the set of photodiodes to couple the source contact with the control contact.

2. The split-SEL CIS pixel physical architecture of claim 1, wherein the source follower block comprises a square-gate source follower (SGSF) transistor with two main-gate regions coupled together to form a square gate structure.

3. The split-SEL CIS pixel physical architecture of claim 2, wherein:
the source contact is coupled with a source-doped region located between the two main-gate regions; and
the drain contact is coupled with a drain-doped region located outside the two main-gate regions.

4. The split-SEL CIS pixel physical architecture of claim 2, wherein the SGSF transistor comprises:
an active layer comprising a source-doped region separated from a first drain-doped region by a first current channel, and separated from a second drain-doped region by a second current channel, wherein:
a first of the two main-gate regions is disposed above the first current channel to a first side of the source-doped region; and
a second of the two main-gate regions is coupled with the first main-gate region and is disposed above the second current channel to a second side of the source-doped region opposite the first side of the source-doped region.

5. The split-SEL CIS pixel physical architecture of claim 4, wherein each of the first current channel and the second current channel has a same nominal channel length.

6. The split-SEL CIS pixel physical architecture of claim 1, wherein the set of photodiodes is a first set of photodiodes, and the pixel block further comprises a second set of photodiodes located below the third oxide diffusion region.

7. The split-SEL CIS pixel physical architecture of claim 1, wherein the set of photodiodes is a two-by-two block of photodiodes.

8. The split-SEL CIS pixel physical architecture of claim 1, further comprising:
a plurality of CIS pixels located adjacent to each other, each CIS pixel comprising:
electrically isolated instances of each of the pixel block, the first oxide diffusion region, the second oxide diffusion region, and the trace; and
an instance of the source follower block disposed on a respective portion of a single, contiguous instance of the third oxide diffusion region.

9. The split-SEL CIS pixel physical architecture of claim 1, wherein a physical gate length of the source follower block is at least double a physical gate width of the source follower block.

10. The split-SEL CIS pixel physical architecture of claim 1, wherein:
the drain contact is coupled with a reference voltage level (Vdd); and
the read-out contact is coupled with a read-out bus.

11. The split-SEL CIS pixel physical architecture of claim 1, further comprising:
an integrated circuit having, integrated thereon, a plurality of instances of each of the a pixel block, the first oxide diffusion region, the second oxide diffusion region, the third oxide diffusion region, and the trace.

12. A split-select-block (split-SEL) source-follower transistor system, comprising:
a source follower transistor disposed on an oxide diffusion region of a pixel architecture, the oxide diffusion region electrically isolated from a select block of the pixel architecture, the source follower transistor comprising:
an active layer comprising a source-doped region separated from a first drain-doped region by a first current channel, and separated from a second drain-doped region by a second current channel; and
a square-gate layer comprising:
a first main-gate region disposed above the first current channel to a first side of the source-doped region; and
a second main-gate region, coupled with the first main-gate region, and disposed above the second current channel to a second side of the source-doped region opposite the first side of the source-doped region.

13. The split-SEL source-follower transistor system of claim 12, wherein the oxide diffusion region is a first oxide diffusion region, and further comprising:
a second oxide diffusion region, electrically isolated from the first oxide diffusion region, and having the select block disposed thereon, the select block including a control contact and a read-out contact; and
a trace to couple the source-doped region with the control contact.

14. The split-SEL source-follower transistor system of claim 12, wherein:
the pixel architecture includes at least a first instance of the source follower transistor located adjacent to a second instance of the source follower transistor and sharing the oxide diffusion region; and
the second drain-doped region of the first instance of the source follower transistor is the first drain-doped region of the second instance of the source follower transistor.

15. The split-SEL source-follower transistor system of claim 12, wherein a physical gate length of each of the first and second main-gate regions is at least double the physical gate width of each of the first and second main-gate regions.

16. The split-SEL source-follower transistor system of claim 12, wherein each of the first current channel and the second current channel has a same nominal channel length.
